(19) United States
(12) Patent Application Publication
(10) Pub. No.: US 2018/0197927 A1
(43) Pub. Date: Jul. 12, 2018

(54) ORGANIC ELECTRONIC DEVICES WITH FLUOROPOLYMER BANK STRUCTURES

(71) Applicant: Merck Patent GmbH, Darmstadt (DE)

(72) Inventors: LI Wei TAN, Eastleigh (GB); Pawel MISKIEWICZ, Southampton (GB)

(21) Appl. No.: 15/580,973

(22) PCT Filed: May 13, 2016
(86) PCT No.: PCT/EP2016/000798

§ 371 Date: Dec. 8, 2017

(30) Foreign Application Priority Data
Jun. 12, 2015 (EP) 15001743.2

(51) Int. Cl. H01L 27/32; H01L 51/56; H01L 51/00; H01L 27/12

(52) U.S. Cl. CPC H01L 27/3246; H01L 51/56; H01L 27/1251; H01L 27/3283; H01L 51/0005

(57) ABSTRACT

An electronic device and methods for its preparation comprising an active area between first and second conductive layers on a substrate; the active area is in a well whose bottom is a patterned first conductive layer on the substrate, the sides of the well are bank structures comprising a non-radiative active fluoropolymer which overlap the edges of the first conductive layer and which are in contact with the substrate. The well contains active materials, preferably introduced by a solution method such as ink-jet. The second conductive layer is located over the top of the well.

Embodiments in accordance with the present invention relate generally to the use of a non-radiative active fluoropolymer as a structure defining material in organic electronic devices, and more specifically to separators, insulating structures or bank structures of such devices and to organic electronic devices comprising such structures, to processes for preparing such structures and to organic electronic devices encompassing such structures.

### BACKGROUND

It would desirable for cost and manufacturability to prepare organic electronic devices such as organic electronic (OE) devices, such as organic field effect transistors (OFETs) or organic light emitting diodes (OLEDs) by deposition of thin film elements (either active or passive materials) in solution on a specific area. Commonly used techniques such as shadow masking using high temperature vacuum deposition are expensive, wasteful of materials and require complicated machinery. One potential solution would be to provide a substrate comprising a patterned bank layer that defines wells into which the active components can be deposited in solution or in liquid form. The wells contain the solution while it is drying or solidifying, such that the active components remain in the areas of the substrate defined by the wells. The solutions can be introduced into the wells using ink-jet as well as other techniques.

Bank structures, and methods of forming them, are known to be used for defining such confined places (wells) on a substrate. For example, US 2007/0023837 A1, WO 2008/117395 A1, EP 1933393 A1, GB 2,458,454 A, GB 2,462,845 A, US 2003/017360 A1, US 2007/190673 A1, WO 2007/023272 A1 and WO 2009/077738 A1 individually and collectively are representative disclosures of such known structures and methods.

Even if a patterned layer of well-defining bank material is provided, problems still exist in containing the solution within the well region and providing good film formation in the well region using solution processing techniques. Uncontrollable wetting of the well-defining bank layer may occur since the contact angle of the solution on the well-defining bank layer is typically low. In the worst case, the solution may overspill the wells.

One of the methods to solve the wetting issue is to treat the surface of the well-defining bank using a fluorine based plasma such as CₓF_{y} or (CF₂)ₓ in order to reduce its wettability prior to depositing the solution. For example, Hirai et al., US 2007/0020899, discloses the use of photopatternable bank layers for creating wells for subsequent filling with active materials by an inkjet method. The patterned banks contain fluorine via post-treatment with fluorine based plasma in order to modify the surface properties of the banks to reduce its wettability. However, plasma treatment can contaminate the exposed device surfaces (such as conductive layers) which can reduce the efficiency and lifetime of the device.

U.S. Pat. No. 8,217,573 and EP 2391187 B1 describes an arrangement in which a non-radiative fluorine-containing polymer, Lumiflon™ (commercially available from Asahi Glass), is used to form a patterned well-defining bank layer when manufacturing electroluminescence (EL) devices. The low-wetting fluorine containing polymer material helps preventing the solution from over-spilling the wells when deposited. However, because the sides of the well are also low-wetting, the solution tends to be thinner at the base of the well leading to non-uniform film formation.

Radiation curable or active fluorine containing photoresists are known. For example, Gunner et al., WO 03/083960, describes the formation of electronic devices by formation of bank structures prepared from a fluoropolymer photoresist. In this reference, passive-matrix OLEDs are prepared by forming wells from rows of bank of photopatternable fluoropolymer over and in an orthogonal direction to patterned rows of a conductive layer (ITO) on a substrate, and filling the wells with organic layers necessary for light-emission by inkjet, followed by a patterned second conductive electrode. Yoshida et al., U.S. Pat. No. 7,781,963 and U.S. Pat. No. 8,217,573, describes the formation of OLEDs by formation of wells using lines of bank structures prepared from a photopatternable fluoropolymer resin, over lines of an electrode, followed by filling in of the wells using an inkjet method. Although the banks of fluoropolymer resin and anode are preferably at right angles, they also can be prepared in parallel rows to the rows of patterned electrode on a substrate. However, this method requires very precise alignment of the edges of the bank so that they correspond exactly to the edges of the patterned conductive electrode. This is difficult to perform in a manufacturing process and leads to increased waste and higher cost. Choi et al., US 2014/0147950, describes OLEDs where the pixels correspond to wells formed by bank structures which are filled with organic layers necessary for light-emission by an inkjet method. The bank structures are made using photopatternable fluoropolymers and can lie over the bottom electrode. Since the organic EL materials do not form layers of uniform thickness because of wetting effects at the walls of the bank, Choi proposes a solution using a wider insulating first bank, under a narrower photoresistive fluoropolymer bank. This insulating first bank prevents the emissive layer from emitting light near the walls of the bank. However, this method reduces aperture size of the pixels. Nakatani et al., EP 2391187, also describes the formation of OLEDs by formation of wells using lines of bank structures prepared from a photopatternable fluoropolymer resin, over lines of an electrode, followed by filling in of the wells using an inkjet method. Fluorinated photoresists that are capable of forming negative profile bank features do not exist at the moment.

Moon et al., IEEE Electron Device Lett., 32(8), 1137 (2011) describes an OTFT made through a process of patterning a photoresist on a substrate, following by spin-coating the patterned substrate with a layer of fluoropolymer (CYTOP™). After baking, the overcoated photoresist was removed by a lift-off process using an organic solvent, forming a well in the layer of fluoropolymer wherever the pattern of photoresist previously existed. A conductive solution of Ag and PEDOT:PSS was deposited in the well to create, after solvent removal, a conductive electrode at the bottom of the well. Subsequent deposition of pentacene and a second electrode completed the OTFT. However, in this method, the bottom electrode lies entirely within the well and so, is limited in width to the distance between the walls of the well. Since resistance increases can be a severe problem for narrow electrodes over a long distance, the devices of Moon cannot be made too small.

U.S. Pat. No. 7,833,612 B2 describes a double layer bank concept whereby the first layer of bank is a photoresist and the second bank layer is a thermally evaporated fluorinated material. US 2007/0020899 describes a method in which a two-layer bank structure is provided which defines a wiring pattern for an electronic substrate. The two-layer bank structure comprises a first layer which has good wettability and a second layer deposited on top of the first bank comprising a low-wetting fluorine containing polymer. These methods require precise mask positioning in order to align the first bank with the mask before the deposition of 2nd bank.

Ulmer et al., U.S. Pat. No. 8,765,224, discloses the formation of fluoropolymer bank structures by depositing a fluoropolymer solution using an inkjet method and curing with heat. However, this method does not provide banks with sharp edges.

McConnell, GB 2462845, and Seok et al., EP 1905800, both disclose the formation of fluoropolymer containing bank structures by depositing a mixture of the fluorocarbon polymer and a photoresist polymer, exposing the mixture in a pattern, and removing the unexposed material. However, this method requires the two different polymers to phase-separate which can be difficult to control uniformly across the device.

Thus it would be desirable to provide fluorinated non-radiative active structure defining materials for use in forming bank structures that are compatible with ink-jet printing and photolithography which provide desirable solution-containing properties. Additionally it would be desirable to provide high resolution methods of forming such bank structures using methods that are both compatible with ink-jet printing and photolithography and do not require the use of processes such as halocarbon reactive ion etching. Still further it would be desirable to provide OE devices manufactured using such desirable structure defining materials and structure forming methods. Finally, there is a need to provide small active areas with electrical connections that allow for adequate power to be delivered without excessive loss due to resistance.

### SUMMARY

Embodiments in accordance with the present invention encompass an electronic device comprising a well area defined by:
a common substrate with an overlying conductive first layer that is patterned into separate sections, each section having an upper surface, at least 3 edges and a distance between each of the edges;
at least three bank structures, each separated by a minimum distance, each in direct contact with both the substrate and at least one first conductive layer sections, each bank structure having a maximum thickness greater than the thickness of the first conductive layer sections, and together form the sides of the well;
all of the edges of at least one first conductive layer section are partially overlapped by a bank structure such that the distances between the edges of the first conductive layer section are all greater than the minimum distances between all of the bank structures so that the exposed upper surface of the conductive layer section forms the bottom of the well;
at least one active layer is located in the well on the exposed first conductive layer section and between the bank structures;
a second conductive layer is located on the active layer(s); and
the bank structures comprise a non-radiative active fluoropolymer.

Some embodiments in accordance with the present invention encompass a method of making the electronic device with non-radiative active fluoropolymer bank structures that overlap conductive layer sections using a negative photoresist process. This method comprises, in order, the steps of:

a) patterning a first conductive layer on a substrate, each section of the first conductive layer having an upper surface, at least three edges and distances between each of the edges;
b) depositing a photoresist over both the substrate and the patterned first conductive layer sections;
c) exposing to radiation regions of the photoresist over each of the first conductive layer sections that are less than the distances between the edges of the sections so there are unexposed regions of photoresist lying along the upper surface of all edges of the section;
d) removing the unexposed photoresist to uncover both the substrate and part of the upper surface of each of the first conductive layer sections along all edges and leaving a section of insoluble exposed photoresist over the first conductive layer whose width is less than every distance between the edges of the conductive layer section;
e) depositing a non-radiative active fluoropolymer layer over the substrate, the upper surface of the first conductive layer along every edge, and remaining insoluble exposed photoresist over the first conduction layer section;
f) removing the remaining insoluble exposed photoresist and its overlying fluoropolymer layer and uncovering the areas of the upper surface of the first conductive layer section, so that at least three fluoropolymer bank structures that each partially overlap the upper surface along each edge of the first conductive layer section and are in contact with the substrate are formed;
g) depositing at least one active layer over and in direct contact with the upper surface of the first conductive layer sections between the fluoropolymer bank structure; and
h) depositing a second conductive layer.

Some embodiments in accordance with the present invention encompass a method of making the electronic device with non-radiative active fluoropolymer bank structures that overlap conductive layer sections using a positive photoresist process. This method comprises, in order, the steps of:

a) patterning a first conductive layer on a substrate, each section of the first conductive layer having an upper surface, at least 3 edges and a distance between each of the edges;
b) depositing a photoresist over both the substrate and the patterned first conductive layer sections;
c) exposing to radiation regions of the photoresist over each of the first conductive layer sections only the regions lying along the upper surface of all of the edges of the section and over at least part of the support and leaving a region of unexposed photoresist over the first conductive layer between the exposed sections; the width of the unexposed section being less than the distances between the edges of the first conductive layer section;
d) removing the exposed photoresist to uncover the both at least part of the substrate and part of the upper surface of each of the first conductive layer sections along each of the edges and leaving a section of insoluble unexposed photoresist whose width is less than every distance between the edges of the conductive layer section;
e) depositing a non-radiative active fluoropolymer layer over the substrate, the upper surface of the first conductive layer along all of the edges, and remaining insoluble unexposed photoresist over the first conduction layer section;
f) removing the remaining insoluble unexposed photoresist and its overlying fluoropolymer layer and uncovering the areas of the upper surface of the first conductive layer section, so that at least three fluoropolymer bank structures that each partially overlap the upper surface along each edge of the first conductive layer section are formed;
g) depositing at least one active layer over and in direct contact with the upper surface of the first conductive layer sections between the fluoropolymer bank structure; and
h) depositing a second conductive layer.

High quality electronic devices with well-defining fluoropolymer bank structures where the conductive layer can be larger than the size of the active areas of the electronic device will minimize power loss due to resistance. The low-wetting properties of fluorocarbon bank structure allow for uniform formation of the active areas while minimizing risk of spillage over the bank structures and improving the uniformity of the film formation. Moreover, devices with these features can be readily manufacturable at low cost with high output using the methods described.

### BRIEF DESCRIPTION OF THE DRAWINGS

Embodiments of the invention are described below with reference to the following drawings. Because the size of the individual components is very small, the drawings are not to scale.

FIG. 1a is a schematic representation of a side view of one embodiment of an electronic device with two adjacent active areas in accordance with the present invention and FIG. 1b is a plane view of the same device.

FIG. 2 is a schematic representation (side view) of a portion of an electronic device showing one embodiment of an electrical connection between the first connective layer and its control element.

FIG. 3 is a schematic representation (side view) of an embodiment where the bank structure overlaps two adjacent conductive sections.

FIG. 4a is a schematic representation (plane view) of an embodiment where the first conductive layer is patterned into stripes and FIG. 4b shows an analogous embodiment where the active area is subdivided within the individual stripes.

FIGS. 5a-5h are schematic representations (plane views) of different shapes for the active area.

FIG. 6 is a schematic representation (plane view) of a subdivided rectangle as the active area.

FIGS. 7a-7h illustrates the steps (side view) of a negative working photoresist process to make an electronic device according to FIG. 3.

FIGS. 8a-8h illustrates the steps (side view) of a positive working photoresist process to make an electronic device according to FIG. 3.

FIG. 9 (plane view) shows a glass/ITO/fluoropolymer bank structure of the invention where the well formed by the fluoropolymer banks was filled with an OLED green emissive material using an inkjet process.

### DETAILED DESCRIPTION

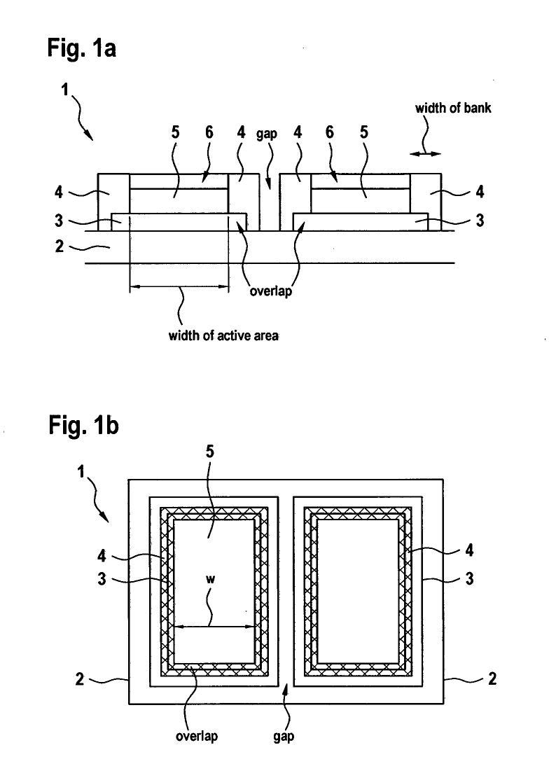

FIGS. 1a and 1b show a schematic representation of a part of the organic electronic device 1 in accordance with the present invention. There is a substrate 2 which is overcoated with patterned sections of a first conduction layer 3. The edges of each section 3 are overlapped with fluoropolymer banks 4 which are also in contact with the substrate 2. Accordingly, each bank structure has a maximum thickness greater than the thickness of the first conductive layer sections. In the well formed by the fluoropolymer banks 4 as the sides and the upper surface of the first conductive electrode 3 as the bottom is an active area 5 which contains functional materials. Over the active area is a second conductive layer 6. Also indicated in FIG. 1a are the width of the active area, the width of the bank, the overlap and a gap between adjacent fluoropolymer banks.

The aforementioned organic electronic device 1 is, for example, a top gate or bottom gate Organic Field Effect Transistor (OFET), including Organic Thin Film Transistors (OTFTs), an Organic Light Emitting Diode (OLED) or an Organic Photovoltaic (OPV) device. Embodiments of the present invention are also inclusive of a product or an assembly comprising an organic electronic device as described above and below. Such product or assembly being an Integrated Circuit (IC), a Radio Frequency Identification (RFID) tag, a security marking or security device containing an RFID tag, a Flat Panel Display (FPD), a backplane of an FPD, a backlight of an FPD, an electrowetting device, an electrophotographic device, an electrophoretic device, an electrophotographic recording device, an organic memory device, a sensor, a biosensor or a biochip. The invention further relates to a process of preparing an organic electronic device, like a top gate OFET or bottom gate OFET, comprising one or more bank structures as described hereinafter. As used herein, the term Organic Field Effect Transistors (OFET) will be understood to be inclusive of the subclass of such devices known as Organic Thin Film Transistors (OTFTs).

The OE devices of the invention are based on having an active or functional layer 5 located between two (3 and 6) electrically conductive layers (electrodes) of opposite charge. As used herein, an “active” or “functional” (terms that can be used interchangeably) layer is one composed of materials that whenever a current or a charge is applied across the two conductive layers, the materials cause a desirable effect. For example, in an OTFT, an applied charge across the conductive layers causes the active layer 5 to change its conductive properties, thereby serving as an electrical switch. For an OLED, application of current between the conductive layers will cause light emission. It should be understood that an “active layer” may include any number of layers that are necessary to provide the desired effect. The “active area” 5 of the OE device are those areas which are energized by the electrically conductive layers and produce the desired effect. For example, the “active area” of an OLED would correspond to the area of the light-emitting pixel.

Appropriate active layer(s) and material(s) therein can be selected from standard materials, and can be manufactured and applied to the electronic device by standard methods. For example, an organic thin-film transistor (OTFT) has an active layer 5 is an organic semiconducting or charge-carrying material; an electrowetting (EW) device has an active layer 5 containing a colored liquid; an organic photovoltaic device (OPV) has an active layer 5 containing a photoactive material; an electroluminescent (EL) device has an active layer 5 containing a material that emits light; and an electrophoretic (EP) device has an active layer 5 containing charged pigment particles dispersed in a liquid. Suitable materials and manufacturing methods for these devices, their components and layers are known to a person skilled in the art and are described in the literature.

The formation of the active layer(s) is accomplished by introducing the appropriate materials in a liquid form or as a solution in a solvent into the wells defined by the fluoropolymer bank structures. The method for applying the materials for the active layer(s) is not critical and may be carried out using a technique such as ink-jet, dispenser, nozzle coating, intaglio printing, letterpress printing or the like. Ink-jet methods are preferred. When the liquid containing the active material is applied with the dispenser, liquid discharge from the dispenser is preferably controlled by suck-back operation or the like at the beginning and the end of the application. When the materials are in liquid form without solvent, they can be solidified into the active layer by appropriate treatment. When the materials are in solution, the active layer is formed by removing the solvent by drying. Equipment, conditions and techniques for these processes are known to a person skilled in the art and are described in the literature.

In addition, it will be understood that the terms “dielectric” and “insulating” are used interchangeably herein. Thus reference to an insulating material or layer is inclusive of a dielectric material or layer and vice versa. Further, as used herein, the term “organic electronic device” will be understood to be inclusive of the term “organic semiconductor device” and the several specific implementations of such devices such as the OFETs as defined above.

As used herein, the terms “orthogonal” and “orthogonality” will be understood to mean chemical orthogonality. For example, an orthogonal solvent means a solvent which, when used in the deposition of a layer of a material dissolved therein on a previously deposited layer, does not dissolve said previously deposited layer.

As used herein, the terms “insulating structure(s)” and “bank structure(s)” will be understood to mean a patterned structure, for example a patterned layer, that is provided on an underlying substrate and defines a specific structure, for example a well, on said substrate that can be filled by a functional material like a semiconductor or a dielectric. The patterned structure comprises a structure defining material that is selected such that a surface energy contrast is created between said patterned structure and the substrate upon which it rests. Usually the substrate has a higher surface energy while the patterned structure has a lower surface energy. The insulating structure or bank structure is used to define more easily the active area of a solution-processed thin film of, for example, the semiconductor in an electronic device, by using the tendency of the liquid solution to move and stick to the area having higher surface energy, i.e., a conductive layer. By confining the liquid in a given area, a thin film can be formed as needed in the specific device application. This provides certain benefits, for example in OFETs the confined area of organic semiconductor improves the off-state current. In OLEDs, the confined area will define a pixel or a line, depending on the number and orientation of the bank structures. It will be understood that the terms “bank structure(s)” and “insulating structure(s)” are used interchangeably herein. Thus reference to a bank structure is inclusive of an insulating structure.

As used herein, the term “substrate” will be understood to mean that base on which the first conductive layer, well-defining bank structures, functional materials within the well and second conductive layer are located. Substrates generally consist of a solid support which can be rigid (for example, glass or thick metal) or flexible (for example, plastic or thin metal). The support may have multiple subbing layers which can be either uniform over the entire surface or patterned. Examples of uniform subbing layers include insulating layers, separation layers, light-absorbing opaque layers, reflective layers, scattering layers, anti-halation layers, planarization layers, adhesion layers and the like. Examples of patterned subbing layers include light-shielding layers, insulating layers, metallization layers, adhesion layers and the like. For many types of OE devices, there will be control elements located on the support either under or adjacent to the active areas of the device. These control elements (for example, TFT circuits) generally receive signals and power from circuitry located in other locations within the device and subsequentially supply and send signals and power to the active areas. These connections are through busses or lines of conductive metals located in the substrate.

As defined herein, the first conductive layer 3 is an electrically conductive layer in contact with the substrate. It is patterned; that is, it is not uniform across the surface of the substrate but is broken up into individual sections according to a regular pattern. The sections of the first conductive layer will underlie (and be larger than) the active areas of the device. The terms “first conductive layer” and “bottom electrode” can be used interchangeably. In practice, each section is connected to a control element that supplies signal and charge through an electrical bus or wiring layers (these are not shown in FIGS. 1a or 1b). It may supply negative charge (for example, as in a cathode) or positive charge (for example, as in an anode). As defined herein, the second conductive layer 6 (which can also be referred to as a “top electrode”) will overlie the active layers and the sections of the first conductive layer sections. It may be patterned in register with the first conductive layer sections or extend uniformly over all the sections of the first conductive layer. It will carry a charge that is opposite to the first conductive layer. The first conductive layer, along with any associated wiring or electrical conductors, may be patterned into sections using known photolithographic techniques on the substrate. The second conductive layer is generally applied by sputtering or other vaporization techniques since the underlying active layers are not generally compatible with photolithography. Patterning of the second conductive layer, when desired, generally requires the use of shadow masks.

For OLEDs, one of the conductive layers should be transparent or nearly transparent (for example, be composed of a transparent metal oxide or a very thin layer of a metal) and the other reflective (for example, a thick layer of metal). For a bottom-emitting OLED, the first conductive layer should be transparent and the second conductive layer should be reflective. For a top-emitting OLED, the first conductive layer should be reflective and the second conductive layer should be transparent.

Suitable electrode materials and deposition methods are known to the person skilled in the art. Such electrode materials include, without limitation, inorganic or organic materials, or composites of the two. Exemplary electrode materials include polyaniline, polypyrrole, poly(3,4-ethylenedioxythiophene) (PEDOT) or doped conjugated polymers, further dispersions or pastes of graphite or particles of metal such as Au, Ag, Cu, Al, Ni or their mixtures as well as sputter-coated or evaporated metals such as Cu, Cr, Pt/Pd, Ag, Au, Mg, Ca, Li or mixtures or metal oxides such as indium tin oxide (ITO), F-doped ITO, GZO (gallium doped zinc oxide), or AZO (aluminium doped zinc oxide). Organometallic precursors may also be used and deposited from a liquid phase.

As used herein, the term “polymer” will be understood to mean a molecule that encompasses a backbone of one or more distinct types of repeating units (the smallest constitutional unit of the molecule) and is inclusive of the commonly known terms “oligomer”, “copolymer”, “homopolymer” and the like. Further, it will be understood that the term polymer is inclusive of, in addition to the polymer itself, residues from initiators, catalysts and other elements attendant to the synthesis of such a polymer, where such residues are understood as not being covalently incorporated thereto. Further, such residues and other elements, while normally removed during post polymerization purification processes, are typically mixed or co-mingled with the polymer such that they generally remain with the polymer when it is transferred between vessels or between solvents or dispersion media.

As used herein, the term “polymer composition” means at least one polymer and one or more other materials added to the at least one polymer to provide, or to modify, specific properties of the polymer composition and or the at least one polymer therein. It will be understood that a polymer composition is a vehicle for carrying the polymer to a substrate to enable the forming of layers or structures thereon. Exemplary materials include, but are not limited to, surfactants, dyes, solvents, antioxidants, photoinitiators, photosensitizers, crosslinking moieties or agents, reactive diluents, acid scavengers, leveling agents and adhesion promoters. Further, it will be understood that a polymer composition may, in addition to the aforementioned exemplary materials, also encompass a blend of two or more polymers.

As defined herein, the terms “photoresist”, “photoresist resin”, “photoresist polymer”, “photopatternable” and “photoresist process” are used interchangeably and refer to the materials and processes well known in the art of photolithography. Unless specifically defined, the materials and process can be positively or negatively working as well known in the art. It can also be water based (for example, poly(methyl acrylimidoglycolate methyl ether or poly(MAGME)). In the context of this invention, the nature of the materials and processes for photolithography to create the sections of the first conductive layer and the well-defining structures are, in general, not critical. It is well within the ability of one skilled in the art to design, select and test appropriate materials and processes to provide the desired structures.

A typical photolithography process involves the steps of cleaning and preparing the substrate, drying the substrate, spin-coating the photoresist resin along with any additives, softbake (typical conditions range from 65° C. for 120 s to 95° C. for 300 s, cooling down, radiation exposure (typical conditions range from 165 to 200 mJ/cm³), post-exposure-bake (optional; typical conditions range from 2 to 120 min at 50 to 120° C. for this step when used), cool to room temperature, relaxation time, development, development, rinsing and dry spinning and a hard bake at 50 to 150° C. for 5 to 120 min.

As defined herein, the terms “fluoropolymer”, “fluorocarbon polymer” or “fluorocarbon” (when used alone and not in conjunction with any further description such as “fluorocarbon surfactant” or “fluorocarbon solvent”) are used interchangeably and refer in general to any polymer that contain both fluorine atoms and carbon atoms.

It is important that the fluoropolymer used to form the bank structures 4 is non-radiative active. In the sense of this inventive, “non-radiative active” means that the material does not change its solubility as a function of exposure to radiation such as X-ray, UV, white or IR light. In other words, it is not a photoresist resin, cannot be used in any kind of photoresist process to create a patterned structure nor forms any sort of patterned structures as a function of differential exposure to any kind of radiation. The fluoropolymer does not contain any photoreactive groups, which will be understood to mean a group that is reactive to actinic radiation during the deposition process. Moreover, the initial step for the deposition process of the fluoropolymer will not involve activation of any species through intentional radiation.

It is also important that the fluoropolymer is orthogonal to the photoresist resin and to the solvents used in a photoresist development process. When deposited over a photoresist resin, it should not intermix with the resin and should remain a solid, separate and distinct layer over the resin. It should not dissolve to any appreciable extent in any of the photoresist processing solutions or solvents used in the process and so, should remain in place after process. However, it should be noted that any fluoropolymer located over a photoresin solubilized during a lift-off process (which is different from the process of removing unexposed (negative process) or exposed (positive process) photoresist during the photolithography steps) will be removed from the device when the underlying photoresist resin is dissolved away. Under such processing conditions, fluoropolymer located over any non-soluble surfaces such as the substrate or the conductive layer should remain substantially intact and unaffected by the processing solutions or solvents used. In other words, the fluoropolymer bank structure is formed by removal of the fluoropolymer in non-bank areas by the dissolution of underlying soluble photoresist in a lift-off process which leaves the bank structures, which have no underlying soluble photoresist, substantially unaffected.

The fluoropolymer may be deposited via a solution process wherein the fluoropolymer is dissolved or suspended in a solvent that is orthogonal to the photoresist materials used to create the sections of the first conductive layer or other elements present on the substrate surface. The solution may be aqueous or use an organic solvent, particularly fluorine containing organic, solvents. The solutions may also contain additional materials that facilitate either the coating process (for example, a surfactant) or the properties of the bank after the process (for example, additional polymeric materials). A particularly useful example of a non-aqueous solvent that is orthogonal to most photoresist processes is 1-methoxy-2-propyl acetate (PGMEA), ethyl lactate, methyl ethyl ketone and ethyl acetate. Examples of fluorinated non-aqueous solvents that are orthogonal to most photoresist processes include Cytop-809M™ (commercially available from Asahi Glass), FC40™, FC43™, FC75™ (all commercially available from Dupont) or HFE7000™ (commercially available from 3M). In some cases, it may be that no additional solvent is necessary. Examples of suitable solution processes include spray-, dip-, web- or spin coating, gravure printing, screen printing, spray-on, ink-jet, embossing, dispensing or block printing. The fluorocarbon polymer may also be applied by a thermal evaporation technique such as plasma generation, chemical vapour deposition (CVD) or physical vapour deposition methodologies. In any case, the fluoropolymer is uniformly deposited over the entire useful surface of the device and is not directly photopatterned.

Suitable examples of fluoropolymers for forming the bank structures include, but are not limited to:
fluorinated poly(p-xylylene) polymers including fluorinated para-Xylylene linear polymers, such as Parylene F, Parylene VT-4, Parylene AF-4 [poly(α,α,α′,α′-tetrafluoro-para-xylylene)], or Parylene HT™ (commercialized by SCS, Specialty Coating Systems), Parylene F corresponding to a fluorinated polymer of formula:

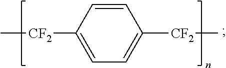

amorphous fluoro polymers, such as cyclic perfluorinated type polymers, for example, Cytop® from Asahi Glass Co., which is a perfluorinated polymer bearing perfluorofurane groups, obtained by cyclopolymerization of perfluoro(alkenylvinylether);

fluorinated polyimide;

Hyflon AD® series (available from Solvay);

polytetrafluoroethylene (PTFE) or fluoro ethylene propylene polymer;

polyvinylidene fluoride (PVDF) or the Kynar® series (commercially available from Arkema);

fluoroethylene Vinyl Ether (FEVE) resins;

fluorinated polynaphthalene;

fluorinated siloxanes such as those described in U.S. Pat. No. 8,883,397 or US 2014/0335452;

fluorinated amorphous carbon thin films (a-C:F);

poly-4,5-difluorodioxoles such as those commercialized by Dupont under the name Teflon® AF series such as AF1601 and Teflon® AF 1600;

fluoro-urethane glycol based polymer such as Cytonix FluorN562; fluorinated poly-cyclic olefins;

fluorinated polynorbonene;

co-polymers consist of fluorinated and non-fluorinated moieties as long as they are soluble in orthogonal solvents;

poly-1,1,2,4,4,55,6,7,7-decafluoro-3-oxa-1,6-heptadiene; and

(CₓF_{y}) and (CF₂)ₓ generated from fluorocarbons by plasma treatment.

Other suitable fluoropolymers may be described in “Modern Fluoroplastics”, edited by John Scheris, John Wiley & Sons Ltd., 1997, Chapter: “Perfluoropolymers Obtained by Cyclopolymerisation” by N. Sugiyama, pages 541ff; “Modern Fluoroplastics”, edited by John Scheris, John Wiley & Sons Ltd., 1997, Chapter: “Teflon AF amorphous fluoropolymers” by P. R. Resnick, pages 397ff; and “High Performance Perfluoropolymer Films and Membranes” V. Arcella et al., Ann. N.Y. Acad. Sci. 984, pages 226-244 (2003).

The fluoropolymer is used as a bank structure material or as a component thereof. It may be the only component or may be mixed with other fluoropolymers, non-polymeric materials (with or without fluorine) or other kinds of non-fluorinated polymeric materials. Such materials include, but are not limited to, surfactants, dyes, solvents, antioxidants, crosslinking moieties or agents, stabilizers, scavengers, leveling agents and in particular, adhesion promoters. In this way, the physical properties of the bank can be designed for the desired effect. For example, the wetting properties can be controlled along the sides of the bank, either uniformly or as a function of distance from the surface of the first conductive layer section to the top of the bank. Dyes can be used to color the fluoropolymer banks to prevent light piping or reflection. The surfaces of the fluoropolymer bank structures may be also post-treated after formation in order to modify its properties.

In some embodiments in accordance with the present invention, the bank structures are post exposure baked at a temperature from 70° C. to 130° C., for example for a period of from 1 to 10 minutes.

In other embodiments in accordance with the present invention, the fluoropolymer bank structure can additionally contain a cross-linkable material that can be cross-linked (after the bank formation) in order to improve one or more properties selected from structural integrity, durability, mechanical resistivity and solvent resistivity of the bank. For modifying the properties of a fluoropolymer containing bank structure, a mixed composition containing the fluoropolymer and a cross-linkable material, only after deposition and subsequent removal of the mixed fluoropolymer composition over the first conductive layer, is exposed to electron beam or electromagnetic (actinic) radiation such as X-ray, UV or visible radiation, or heated if the cross-linkable contains thermally crosslinkable groups. It is important to note that this step is performed only after formation of the fluoropolymer bank structure and is not involved with the formation or patterning of the banks. The purpose of such exposure to actinic radiation and/or heat is to cause crosslinking of cross-linkable materials within the bank structures and thereby modify the physical properties of the previously formed banks. As previously noted, the fluoropolymer is non-radiative active and does not contain any photoreactive groups. Suitable radiation sources include mercury, mercury/xenon, mercury/halogen and xenon lamps, argon or xenon laser sources, X-ray and can be uniform over the device or specific to the location of the bank structures.

There may be layers located between the fluoropolymer bank and either the first conductive layer, the substrate or both. These layers, if present, should be considered to be part of the first conductive layer or the substrate. They may or may not extend past the boundary of fluoropolymer bank structure. They may supply an insulating function (for example, a layer of SiO₂) or modify the wettability at the base of the bank structure.

One of the problems associated with OE devices is power loss associated with the electrical connections to a patterned first conductive layer (the bottom electrode). If the pattern is effectively a one dimensional stripe or line that extends from one end of the useful area of the device to the other (for example, in a passive-matrix OLED), then the voltage will decrease along the strip from the control element (at one edge of the device) due to resistance. This results in uneven and non-uniform effects and limits the overall size of the device. One way to minimize this loss in a stripe pattern is to use a wider stripe of conductive material (it is generally undesirable to use a thicker layer of conductive material as this approach makes the entire device thicker). However, this results in larger active areas and a loss in display resolution.

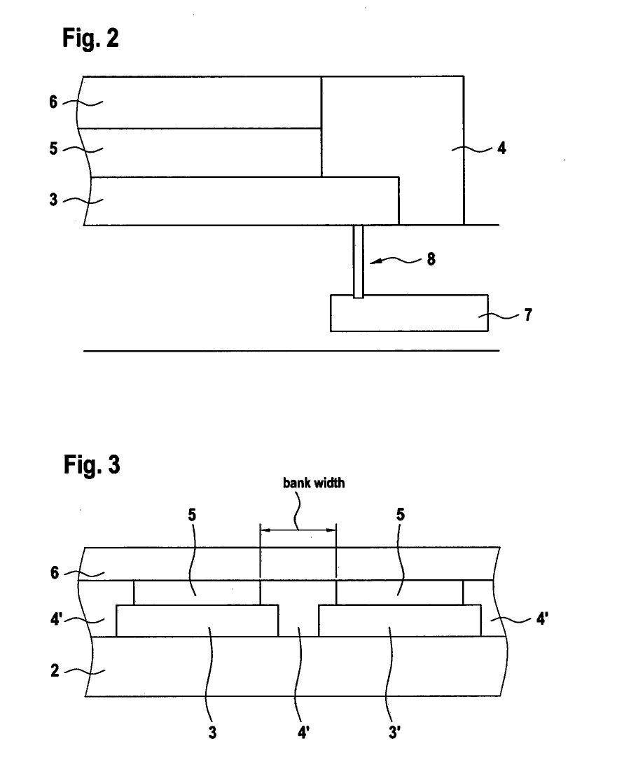

For two dimensional patterns (for example, a matrix of pixels typical of active matrix OLEDs), the first conductive layer is divided into sections that correspond to the active areas. Because it is necessary to have at least one control element (and often more) per individual section, it is necessary to locate the control element near the section that is to be controlled. Thus, the control elements can either be located adjacent (laterally displaced along the substrate) to active areas or below (vertically displaced into the substrate) the active area. However, if the control element is adjacent to the active area, then the amount of space for the active areas is limited and display resolution will be decreased. If the control element is located below the active area, there must be a vertical connection from the control element to the bottom electrode of sufficient size to carry the necessary power. However, this connection should not be directly within the active area since the connection area needs to be large (to ensure proper vertical alignment and connection during manufacturing) but having a large connection area perturbs the uniformity of the bottom electrode, leading to variations in performance between active areas. To avoid these problems in this situation, it is best to make the connection away from the active area, which requires having a bottom electrode that is larger in size than the active area. This embodiment is illustrated in FIG. 2, where there is a control element 7 located within and as part of the substrate 2. There is a vertical electrical connection 8 that connects to the first conductive layer section 2 in a region underneath the overlapping fluorocarbon bank 4 and outside the active area 5.

The inventive OE device has a first conductive layer section that is bigger than the active area. In such OE devices, the active areas are defined by having fluoropolymer banks that partially overlap the first conductive layer along all sides of first conductive layer section. This creates a well in which the entire bottom part of the well is the upper surface of the first conductive layer and the sides of the well are the fluoropolymer banks. The well area between the banks, whose bottom surface is the upper surface of the first conductive layer, contains active layers which are contained by the fluorocarbon banks. There is a second conductive layer over the active layer. Because the first conductive layer section is larger than the active area, it can either be made wider (to decrease resistance) than the active area in some embodiments or in other embodiments, allow for connection of the first conductive layer section to control elements in a location outside the active area.

It is important that the fluorocarbon banks partially overlap all edges of the first conductive layer section so that when a solution of active materials is introduced into the well, it is fully contained within the well by the upper surface of the conductive layer on the bottom and by the fluoropolymer bank structures on the sides. The fluoropolymer banks also separate one active area from an adjacent active area as shown in FIG. 1a. In this embodiment, a fluoropolymer bank structure will not extend all of the way to the adjacent section which will have its own fluoropolymer bank structure along its edge. In this embodiment, there will be a gap or space on the substrate between the two neighboring fluoropolymer bank structures as shown in FIG. 1a. In some cases, this gap between the two banks may be filled (for example, with an insulating planarization material or a conductive metal bus).

In another embodiment, a fluoropolymer bank structure will entirely occupy the space between adjacent or neighboring first conductive layer sections. In this embodiment, a single fluoropolymer bank structure will overlap one edge of two different conductive layer sections. This is illustrated in FIG. 3, where a single fluoropolymer bank. 4′ is in contact with two adjacent first conductive layer sections, 3 and 3′ as well as the substrate between the sections.

The relative minimum width of the active area to the width (measured from the edge of the bank that overlaps the first conductive layer section to the opposite edge where it meets the substrate or another conductive layer section as shown in FIGS. 1a and 3) of the fluoropolymer bank structures is a matter of device type and design since these factors influence the resolution. This is because as the banks structures become wider, the active areas will be farther apart from each other. For example, for an OLED where the active areas are rectangular in shape, the following table shows one representative relationship between these elements for one display size:

| Display Resolution | Width of Active Area | Bank Width |
|---|---|---|
| (pixels per inch, ppi) | (μm) | (μm) |
| 100 | 75 | 10 |
| 200 | 32 | 10 |
| 300 | 23 | 5 |
| 400 | 16 | 5 |
| 500 | 12 | 5 |

For OLED embodiments, the total of the two opposing bank widths should be less than the width of the active area in order to minimize the distance between active areas. It is preferred that the minimum width of the active area be at least 1.5 times, and more preferably 2 times, the width of two opposing banks in the same direction as the minimum width of the active area. For example, if the bank width of each bank is 10 μm, the total width is 20 μm, so the minimum width of the active area should be at least 30 μm, or more preferably, at least 40 μm. It is understood that one skilled in the art would be able to determine the size of the active areas and banks appropriately based on the aims and design of the device.

It is important that the fluorocarbon bank overlaps the edge of the first conductive layer section and extend over the edge so that it is also in contact with the substrate (or in some embodiments, another conductive section) and covers the vertical edge of the first conductive layer section. This helps to prevent accidental short-circuiting between the sections during manufacturing by debris. For most devices, the overlap (that is, the distance from the edge of the first conductive layer section to the edge of the fluoropolymer bank structure on the upper surface of the first conduction layer section as shown in FIG. 1a) should be a minimum of around 100 nm, and preferably at least 250 nm and most preferably at least 500 nm. Alternatively, since the width of the active area depends on the type of device and its design, when the width is small (less than 8 μm), the degree of overlap by the fluorocarbon bank should be less than ⅛, or more preferred ⅙ than the minimum width of the first conductive layer section, but not less than 100 nm.

Generally the thickness of an active layer (for example a gate dielectric or semiconductor layer in an OTFT) in some preferred electronic device embodiments according to the present invention is from 0.001 μm (in case of a monolayer) to 10 μm. In other embodiments such thickness ranges from 0.001 to 1 μm, and in still other embodiments from 5 nm to 500 nm, although other thicknesses or ranges of thickness are contemplated and thus are within the scope of the present invention. Since the fluoropolymer bank structure defines a well which will contain the active layers, the height of the fluoropolymer bank over the first conductive layer should be at least be sufficient to prevent overflow of the active layers as applied. It should be understood that in the cases when the active material is applied as a liquid or solution, the maximum height of the solution could be greater than the height of the fluoropolymer bank structures because of its non-wetting properties.

Upon removal of the solvent, the height of the fluoropolymer bank structure (either the overlapping bank or any subdividing bank) over the conductive layer should be the same or greater than the thickness of the active layers. In the case where the height of the fluoropolymer bank structure is significantly greater than the thickness of the active layers, the second conductive layer may be located on top of the active layers and within the fluoropolymer banks (this is illustrated in FIG. 1a). Alternatively, material can be added to the active area to increase its thickness to be the same as the bank height if necessary. If the height of the fluoropolymer bank structure is only slightly greater or the same as the thickness of the active layers, then the second conductive layer can be deposited uniformly over all of the active areas and bank tops if desired (this is illustrated in FIG. 3). It is understood that whether the second conductive layer is limited to the active area or is in common with all active areas is independent of the particular embodiments shown in FIGS. 1a and 3.

Since the active area has a finite size which implies that there will be a minimum of 3 bank structures, there must be some minimum distance between any two banks (or opposing sections of the bank if the bank is non-linear). Since the active area is not limited to any particular shape, the banks do not necessarily have to be linear or parallel to each other.

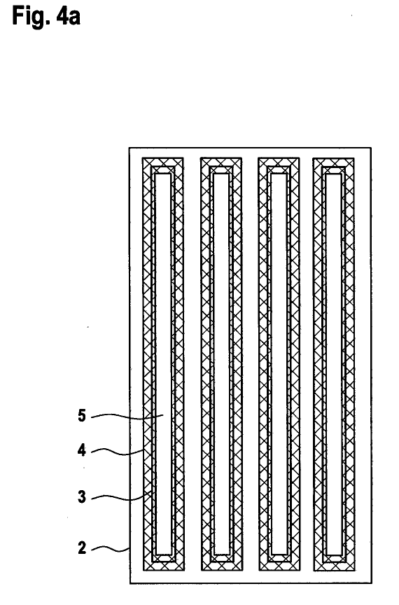

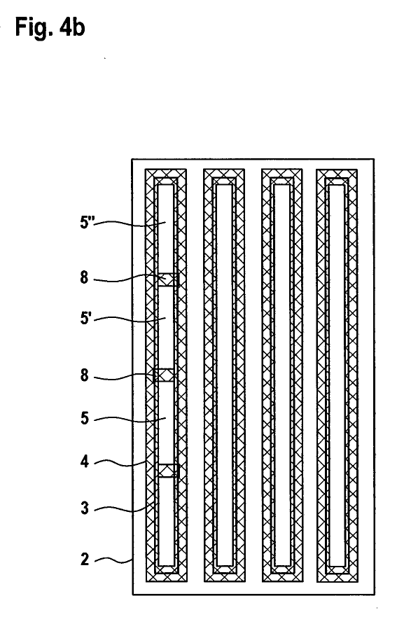

The simplest case is where the pattern of the first conductive layer sections are multiple parallel stripes that runs from one end of the device to the other (as in a passive matrix OLED device). This creates rectangular first conductive layer sections where the length is much greater than the width. In this embodiment, the banks overlap the edges along the length (the longest direction) of the section and the minimum distance between the banks is smaller (because of the overlap) than the width (the smallest direction) of the section. In one embodiment, the corresponding well, which will define the active area once the active layer and second conductive layer are introduced, is in the shape of a rectangular stripe which is smaller in width than the stripe of the first conductive layer. This is shown in FIG. 4a (2^{nd} conductive layer is not included for clarity) where the first conductive layer 3 is patterned into long parallel stripe sections.

The above embodiment describes one well or active area for each first conductive layer section. However, in other embodiments, the well may be subdivided into two or more subsections by the addition of additional fluorocarbon banks 8 as shown in FIG. 4b. The additional banks 8 will lay entirely on top of the first conductive layer section and totally within the boundary of the well set by the fluoropolymer banks that overlap the edges of the section. It should be understood that the well (and the resulting active area) is defined only by the fluoropolymer banks that overlap the edges of the first conductive layer section. This is because these smaller subdivisions (5, 5′, 5″, etc) of the well are not individually controlled since they all share the same first conductive layer section. The fluoropolymer banks that subdivide the well can be made by the appropriate exposure during the photoresist process that creates the well-defining fluoropolymer banks.

The subdivision of the well has the advantage of more uniform distribution of active material within each smaller well. In this case, all subdivisions will contain the same formulation of active layers. Alternatively, the subdivisions could each be filled with different materials. This results in different subsections having a different active layer. For example, one embodiment for an OLED would have RGB stripes where the first conductive layer sections are parallel stripes. The active layers, overlying these conductive stripes, can be composed of the same material along its length. However, subdivisions of the well could be made by the addition of perpendicular banks across the width of the stripes of the first conductive layer. Each subdivision could then be filled with a different formulation. As an example, a single blue stripe could have sections with a short blue emission alternating with sections with a deep blue emission along its length, effectively resulting in broader blue emission and improved color reproduction.

There is no requirement that the shape of the active area correspond or be analogous in shape to the section of first conductive layer, so long that the active area defined by the fluoropolymer banks is smaller than the first conductive layer section so that the entire bottom of the well is the upper surface of the first conductive layer section.

Another more complicated pattern is a two dimensional matrix of first conductive layer sections. While the individual first conductive layer sections can be unlimited in shape, it is much preferred that they be rectangular or square in shape for ease of manufacturing. If the shape is rectangular, then it has a length and a width where the length is greater than the width (in a square, length=width). If the section is another shape (for example, an oval or a circle), then there will still be a minimum distance across the section from one edge to an opposite edge.

Even when the first conductive layer sections are in the form of rectangles or squares, there is no need for the active areas correspond to these shapes. Research has shown that some shapes are preferred than others for printing layer uniformity and pixel coverage. Depending on the needs of the device and the nature of the active materials used to create the active layers, the overlapping fluorocarbon bank structures can be used to define wells of different shapes. However, no matter what the shapes of the well, the fluoropolymer banks need to overlap all edges of the first conductive layer so that the entire bottom of the well is the upper surface of the first conductive layer.

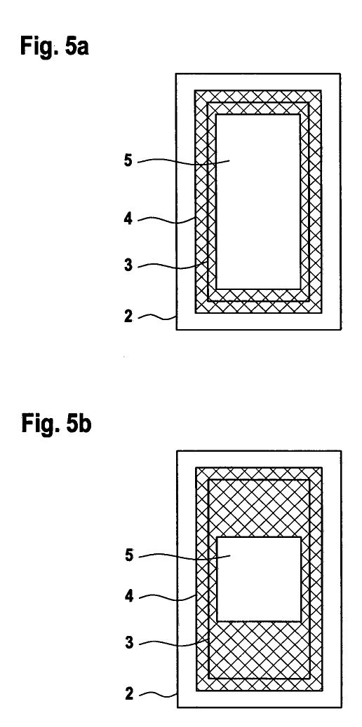

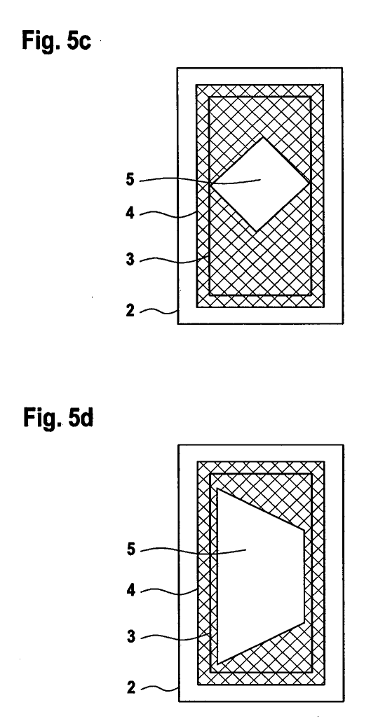

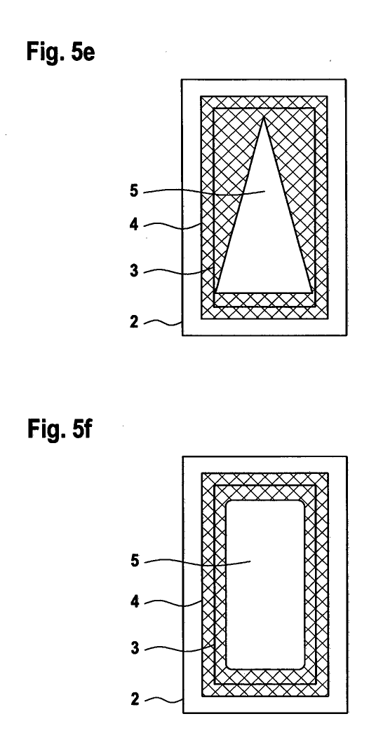

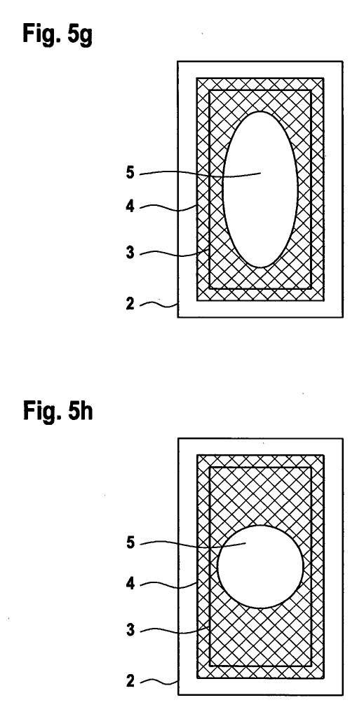

As shown in FIG. 5a-5h, the shapes of the wells (and the resulting active areas) can include, but are limited to, rectangles (FIG. 5a), squares (FIG. 5b) diamonds (FIG. 5c), trapezoids (FIG. 5d) or triangles (FIG. 5e). All of these may have rounded corners at intersections where straight lines meet (for example, FIG. 5f). The shapes may also be those without any linear sides such as ovals (FIG. 5g) or circles (FIG. 5h). FIGS. 5a-5h utilize a rectangular first conductive layer section 3 for illustration but other section shapes are possible and any of these shapes may or may not correspond to the shape of the first conductive layer section. For some shapes (for examples, squares and circles), a square conductive layer section shape may be preferred. However, all of the shapes will still have minimum distances between banks (or bank segments) that is smaller than the minimum distances between the edges of the first conductive layer section (as shown in FIGS. 5a-h).

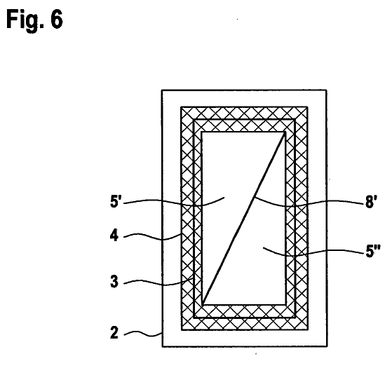

Any of the above shapes can be divided into two or more subdivisions. For example, FIG. 6 shows a rectangular shaped active area that is divided into two triangular subsections, 5′ and 5″ by an additional bank 8′. Such subsections may contain the same functional materials or the materials may be different.

Depending on the needs of the device and the materials of the active layer, the profile of the fluoropolymer bank may be positive (broader at the bottom (closest to the substrate) and narrower at the top) or negative (narrower at the bottom and broader at the top). These profiles can be formed as a result of the photoresist process used to introduce the fluoropolymer bank structures. Negative bank structures are preferred.

The claimed OE device may be made using a negative working or a positive working photoresist on a prepared substrate. Both of these photoresist processes are well known. Although the materials used may be different, the basic steps in each method are very similar and differ mostly which regions are exposed and subsequentially removed.

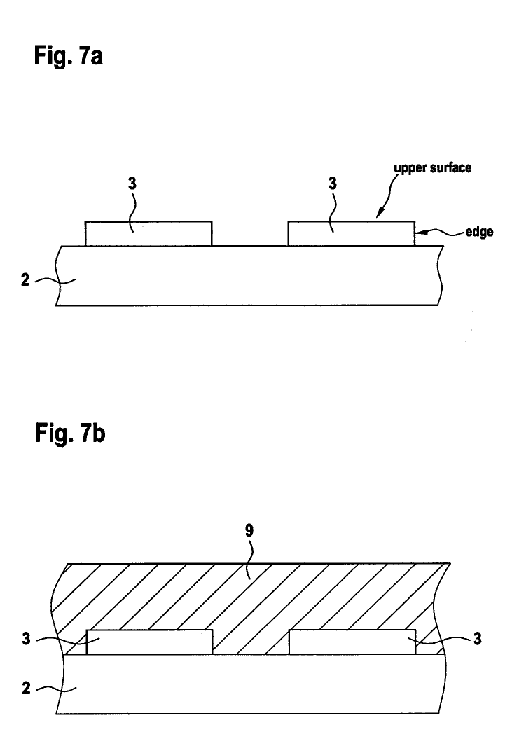

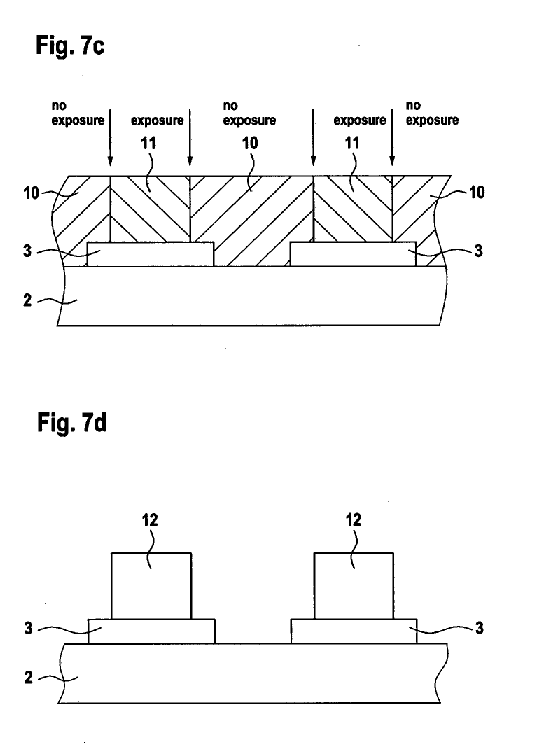

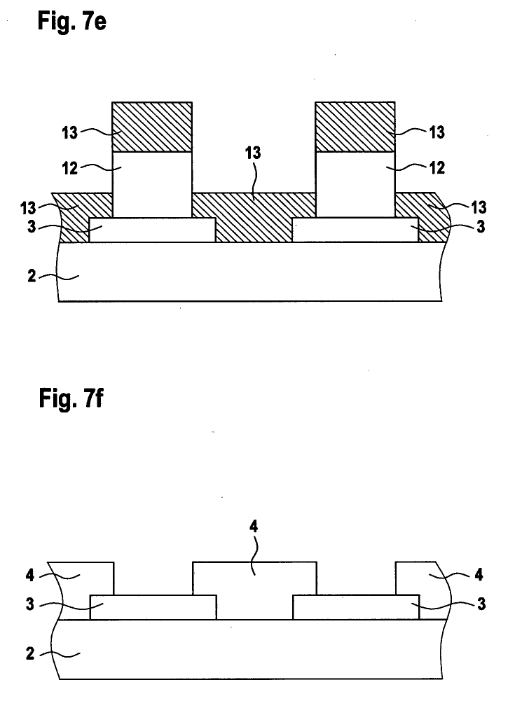

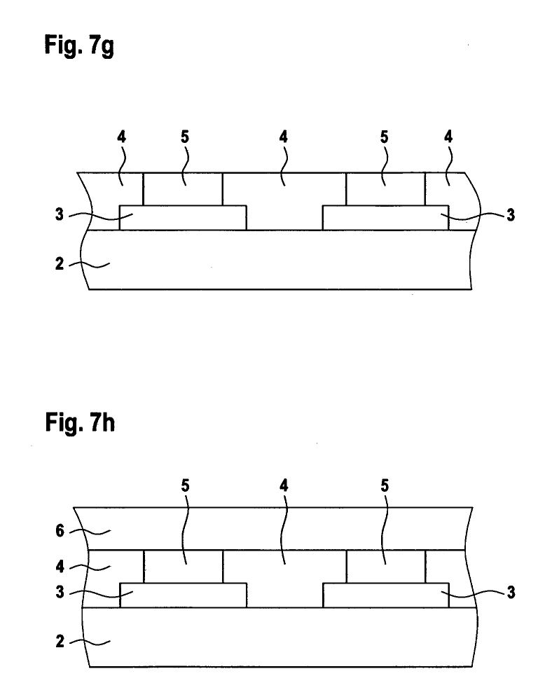

One method (as shown in FIGS. 7a-7h) that can be used to prepare the OE device 1 according to the embodiment shown in FIG. 3 is based on a negative working photoresist process. It comprises, in order, the steps of:

a) patterning a first conductive layer 3 on a substrate 2, each section of the first conductive layer having an upper surface, at least three edges and distances between each of the edges;
b) depositing a photoresist 9 over both the substrate 2 and the patterned first conductive layer sections 3;
c) exposing to radiation regions of the photoresist 11 over each of the first conductive layer sections 3 that are less than the distances between the edges of the sections 3 so there are unexposed regions 10 of photoresist lying along the upper surface of all edges of the section 3;
d) removing the unexposed photoresist 10 to uncover both the substrate 2 and part of the upper surface of each of the first conductive layer sections 3 along all edges and leaving a section of insoluble exposed photoresist 12 over the first conductive layer 3 whose width is less than every distance between the edges of the conductive layer section 3;
e) depositing a non-radiative reactive fluoropolymer layer 13 over the substrate 2, the upper surface of the first conductive layer 3 along every edge, and remaining insoluble exposed photoresist 12 over the first conduction layer section 3;
f) removing the remaining insoluble exposed photoresist 12 and its overlying fluoropolymer layer 13 and uncovering the areas of the upper surface of the first conductive layer section 3, so that at least three fluoropolymer bank structures 4 that each partially overlap the upper surface along each edge of the first conductive layer section 3 and are in contact with the substrate are formed;
g) depositing at least one active layer 5 over and in direct contact with the upper surface of the first conductive layer sections 3 between the fluoropolymer bank structure 4; and
h) depositing a second conductive layer 6.

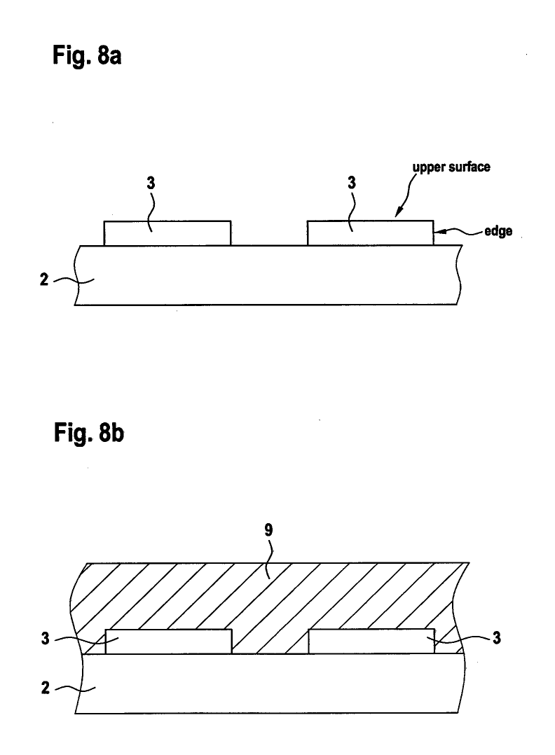

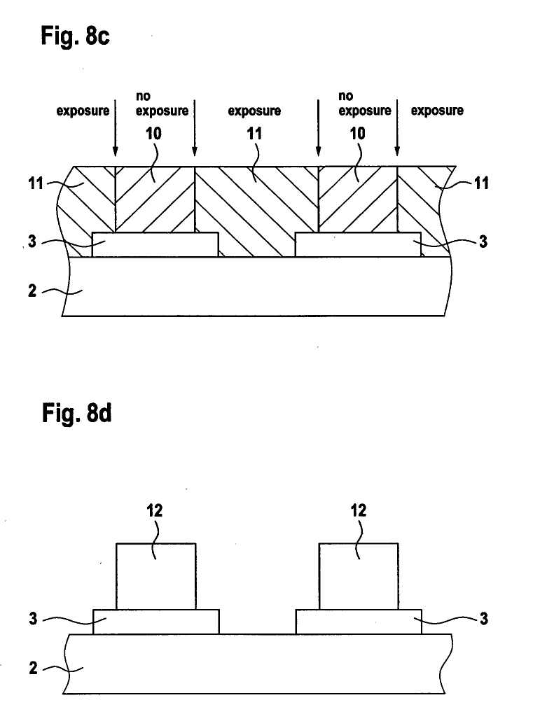

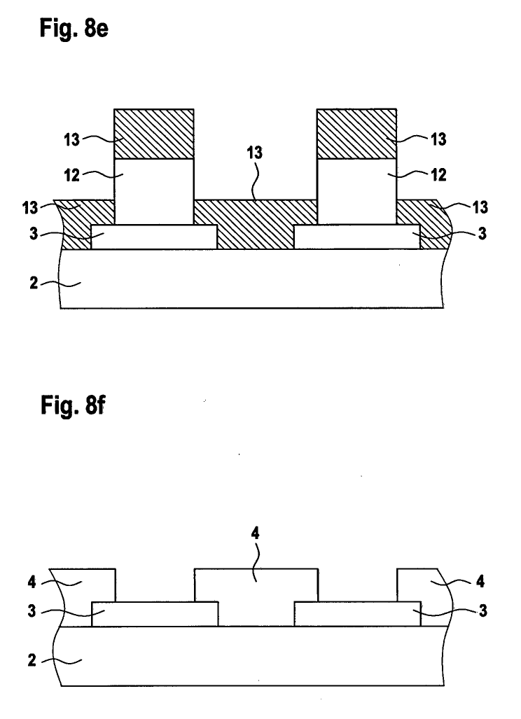

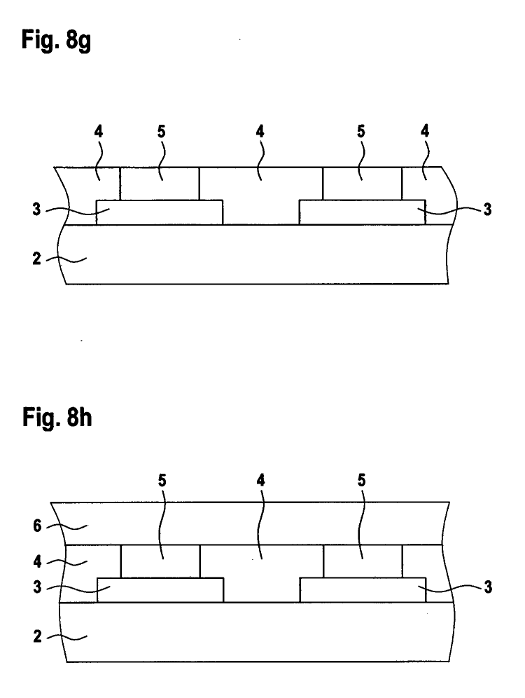

Another method (as shown in FIGS. 8a-8h) that can be used to prepare the OE device 1 according to the embodiment shown in FIG. 3 is based on a positive working photoresist. It comprises, in order, the steps of:

a) patterning a first conductive layer 3 on a substrate 2, each section of the first conductive layer 3 having an upper surface, at least 3 edges and a distance between each of the edges;
b) depositing a photoresist 9 over both the substrate 2 and the patterned first conductive layer sections 3;
c) exposing to radiation regions of the photoresist 11 over each of the first conductive layer sections 3 only the regions lying along the upper surface of all of the edges of the section and over the support 2 and leaving a region of unexposed photoresist 10 over the first conductive layer 3 between the exposed sections 11; the width of the unexposed section 10 being less than the distances between the edges of the first conductive layer section 3;
d) removing the exposed photoresist 11 to uncover the both the substrate 2 and part of the upper surface of each of the first conductive layer sections 3 along each of the edges and leaving a section of insoluble unexposed photoresist 12 whose width is less than every distance between the edges of the conductive layer section 3;
e) depositing a non-radiative reactive fluoropolymer layer 13 over the substrate, the upper surface of the first conductive layer 3 along all of the edges, and remaining insoluble unexposed photoresist 12 over the first conduction layer section 3;
f) removing the remaining insoluble unexposed photoresist 12 and its overlying fluoropolymer layer 13 and uncovering the areas of the upper surface of the first conductive layer section 3, so that at least three fluoropolymer bank structures 4 that each partially overlap the upper surface along each edge of the first conductive layer section 3 are formed;
g) depositing at least one active layer 5 over and in direct contact with the upper surface of the first conductive layer sections 3 between the fluoropolymer bank structure 4; and
h) depositing a second conductive layer 6.

While both of these methods are according to the embodiment shown in FIG. 3, it is understood that they both also could be applied to the embodiment of FIG. 1a as well by changing the exposure regions.

In both of the above processes, the insoluble photoresist 12 not removed during the process of step c) is used to generate the location and structure of the fluoropolymer banks 4. The fluoropolymer 13 is coated uniformly over all surfaces including the remaining insoluble (undeveloped) photoresist 12. The remaining photoresist is located in the areas that the fluoropolymer needs to be removed to create the wells for the active layers. A lift-off process then removes insoluble photoresist 12 and its overcoat of fluoropolymer 13. Additionally, by controlling the shape of the edges of remaining insoluble photoresist 12, the edge shape of the fluoropolymer bank structures 4 remaining after the lift-off process can be determined.

The lift-off and removal of the photoresist 12 and overlying fluoropolymer layer 13 can be any process that is capable of removing the desired materials and is orthogonal to the remaining structures and surfaces of the device. Typically, this involves soaking or bathing the device in an orthogonal solvent for a period of time. Elevated temperatures may be used as well as ultrasonic vibrations to help loosen the photoresist. Some examples for a lift-off solvent include DMSO, N-methylpyrrolidone and acetone. Mechanical processes (although not always desirable) such as wiping or scrapping may be additionally employed in conjunction with solvent treatment. It is also possible to use a photoresist that chemically reacts with a component in the process solution so that is dissolves readily in the solution or is otherwise released from the surface of the first conductive layer.

In order to assist with lift-off and removal of the insoluble photoresist 12 and overlying fluoropolymer layer 13, the thickness of the insoluble photoresist layer 12 should be greater than the thickness of the overlying fluoropolymer 13. This is because penetration of the solvent needs to come from the vertical edge of the insoluble photoresist 12. In both of the positive and negative working methods above, it is preferred that the thickness of the insoluble photoresist layer 12 created in step d) is at least 2 times thicker than the thickness of the fluoropolymer layer 13 deposited in step e), more preferably at least 5 times thicker or even 10 or more times thicker. Moreover, it is preferred to use a process that results in the insoluble photoresist 12 having a negative profile in order to increase solvent penetration into the photoresist 12 and improve lift-off.

In order to avoid lift-off of the desirable fluoropolymer bank structures 4, it is important that the bank structures 3 adhere strongly to the substrate 2. The adhesion of the fluorocarbon to the substrate must be high, preferably greater than 10 N/mm² (10 MPa) or more preferably greater than 20 N/mm² (20 MPa). In some cases, an underlying layer may be used to increase adhesion between the substrate and the fluoropolymer. This adhesion layer may be a subbed layer that is uniform across the substrate, may be patterned prior to the photoresist process which may or may not extend past the boundaries of the fluoropolymer bank structure. Alternatively, an adhesion layer may be introduced in a separate step after the photoresist process but before the introduction of the fluoropolymer. Some example of adhesion promoting materials would be BONDiT™ (commercially available from Reltex Company) or those disclosed in U.S. Ser. No. 07/016,6469, U.S. Pat. No. 8,530,746 or U.S. Pat. No. 8,617,713. It is understood that that when such an adhesive layer is present, it is considered part of the substrate.

The invention will now be described in more detail by reference to the following examples, which are illustrative only and do not limit the scope of the invention. Above and below, unless stated otherwise percentages are percent by weight and temperatures are given in degrees Celsius (° C.).

### Example 1

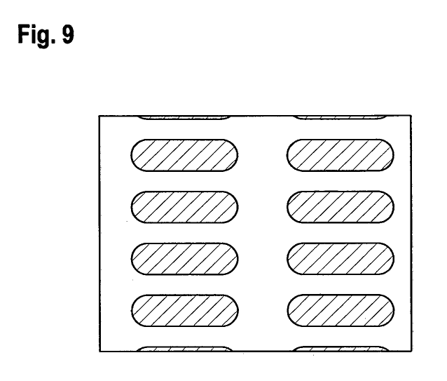

Bank Structure Formation in OLED Devices: Layers of ITO of different thicknesses (either 50 nm or 150 nm) were patterned into (0.5 mm×20 mm) strips on a glass substrate by wet etching. A negative working photoresist (AZ5214E™; available from MicroChemical Company) was spin-coated over the ITO and glass surface to form a 2000 nm thick uniform layer. The photoresist was dried on a hotplate at 110° C. for 2 min. Then, the photoresist was exposed under i-line (365 nm) UV light with a photomask using mask aligner at dosage around 60 mJ/cm² followed by post-exposure bake (PEB) at 120° C. for 2 min. Then the sample was flood exposed using i-line (365 nm) UV light without a photomask at dosage 250 mJ/cm². The sample was developed in TMAH 2.35% aqueous solution for 1 min followed by DI water rinsing for several time before spin dry and anneal at 100° C. to remove water from the sample to create a 210×80 μm² block of insoluble photoresist in the location where the active layer will be eventually located. The photoresist lying along the edges of the ITO was removed during the process so that the upper surface of the ITO along both the edges was uncovered. For both layer thicknesses, the uncovered portion of the ITO was about 140 μm on each edge. A 300 nm layer of Cytop-809M™ fluoropolymer was spin-coated over the glass and dried at 100° C. for 2 min. This created a layer of Cytop-809M on the surface of the substrate, the upper surface of the ITO along its edges and the insoluble photoresist in the active area. The insoluble photoresist and its overlying Cytop-809M layer was then stripped from the glass substrate using DMSO at 60° C. in an ultrasonic bath for 1 hour. The sample was spin-dried and annealed at 100° C. for 2 mins. The resulting devices have fluoropolymer bank structures overlapping an ITO bottom electrode both along the upper surfaces along the edges together with the vertical edge extending to the substrate. Both ITO thicknesses gave similar results. As shown in FIG. 9, filling the well with layers of OLED materials via inkjet deposition and deposition of a top electrode will complete the device fabrication.

Unless the context clearly indicates otherwise, as used herein plural forms of the terms herein are to be construed as including the singular form and vice versa.

It will be appreciated that variations to the foregoing embodiments of the invention can be made while still falling within the scope of the invention. Each feature disclosed in this specification, unless stated otherwise, may be replaced by alternative features serving the same, equivalent or similar purpose. Thus, unless stated otherwise, each feature disclosed is one example only of a generic series of equivalent or similar features. All of the features disclosed in this specification may be combined in any combination, except combinations where at least some of such features and/or steps are mutually exclusive. In particular, the features of the invention are applicable to all aspects of the invention and may be used in any combination. Likewise, features described in non-essential combinations may be used separately (not in combination).

1.-27. (canceled)

28. An electronic device comprising a well area defined by:
a common substrate with an overlying conductive first layer that is patterned into separate sections, each section having an upper surface, at least 3 edges and a distance between each of the edges;
at least three bank structures, each separated by a minimum distance, each in direct contact with both the substrate and at least one first conductive layer sections, each bank structure having a maximum thickness greater than the thickness of the first conductive layer sections, and together form the sides of the well;
all of the edges of at least one first conductive layer section are partially overlapped by a bank structure such that the distances between the edges of the first conductive layer section are all greater than the minimum distances between all of the bank structures so that the exposed upper surface of the conductive layer section forms the bottom of the well;
at least one active layer is located in the well on the exposed first conductive layer section and between the bank structures;
a second conductive layer is located on the active layer(s); and
the bank structures comprise a non-radiative active fluoropolymer.

29. The electronic device according to claim 28, wherein the device is an organic thin-film transistor (OTFT) where at least one active layer is an organic semiconducting or charge-carrying material.

30. The electronic device according to claim 28, wherein the device is an electrowetting (EW) device where at least one active layer contains a colored liquid.

31. The electronic device according to claim 28, wherein the device is an organic photovoltaic device (OPV) where at least one active layer contains a photoactive material.

32. The electronic device according to claim 28, wherein the device is an electroluminescent (EL) device where at least one active layer contains a material that emits light.

33. The electronic device according to claim 32, wherein the minimum width of the active area is at least 1.5 times the total width of the two opposing banks.

34. The EL device according to claim 32, wherein the first conductive layer is transparent and the second conductive layer is an opaque metal so that light is emitted through the substrate.

35. The EL device according to claim 34, wherein the first conductive layer is an opaque metal and the second conductive layer is transparent so that light is emitted from the side of the device opposite to the substrate.

36. The electronic device according to claim 28, wherein the device is an electrophoretic (EP) device where the at least one active layer contains charged pigment particles dispersed in a liquid.

37. The electronic device according to claim 28, wherein the non-radiative active fluoropolymer is selected from the group consisting of fluorinated poly(p-xylylene) polymers; amorphous fluoro polymers, fluorinated polyimides; Hyflon AD® series; polytetrafluoroethylene (PTFE); fluoro ethylene propylene polymers; polyvinylidene fluorides; fluoroethylene Vinyl Ether (FEVE) resins; fluorinated polynaphthalenes; fluorinated siloxanes; fluorinated amorphous carbon thin films (a-C:F); poly-4,5-difluorodioxoles; fluoro-urethane glycol based polymers; fluorinated poly-cyclic olefins; fluorinated polynorbonene; poly-1,1,2,4,4,55,6,7,7-decafluoro-3-oxa-1,6-heptadiene; and (CₓF_{y}) and (CF₂)ₓ.

38. The electronic device according to claim 28, wherein the overlap of the fluoropolymer bank structure on the upper surface of the first conduction layer section is at least 500 nm.

39. The electronic device according to claim 28, wherein a single fluoropolymer bank structure will overlap one edge of two different conductive layer sections.

40. The electronic device according to claim 28, wherein there is a gap between the two adjacent fluoropolymer bank structures of adjacent first conductive layer sections.

41. The electronic device according to claim 28, wherein the shape of the active area defined by the fluoropolymer bank structures are selected from the group of rectangles, squares, diamonds, trapezoids, triangles, ovals and circles.

42. The electronic device according to claim 28, wherein the well over each first conductive section is subdivided into two or more subsections by the addition of additional fluorocarbon banks.

43. The electronic device according to claim 42, wherein different subsections have a different active layer.

44. The electronic device according to claim 28, wherein the sides of the fluorocarbon bank have a negative profile.

45. A method of forming the electronic device according to claim 28, wherein the device comprises, in order, the steps of:
a) patterning a first conductive layer on a substrate, each section of the first conductive layer having an upper surface, at least three edges and distances between each of the edges;
b) depositing a photoresist over both the substrate and the patterned first conductive layer sections;
c) exposing to radiation regions of the photoresist over each of the first conductive layer sections that are less than the distances between the edges of the sections so there are unexposed regions of photoresist lying along the upper surface of all edges of the section;
d) removing the unexposed photoresist to uncover both the substrate and part of the upper surface of each of the first conductive layer sections along all edges and leaving a section of insoluble exposed photoresist over the first conductive layer whose width is less than every distance between the edges of the conductive layer section;
e) depositing a non-radiative active fluoropolymer layer over the substrate, the upper surface of the first conductive layer along every edge, and remaining insoluble exposed photoresist over the first conduction layer section;
f) removing the remaining insoluble exposed photoresist and its overlying fluoropolymer layer and uncovering the areas of the upper surface of the first conductive layer section, so that at least three fluoropolymer bank structures that each partially overlap the upper surface along each edge of the first conductive layer section and are in contact with the substrate are formed;
g) depositing at least one active layer over and in direct contact with the upper surface of the first conductive layer sections between the fluoropolymer bank structure; and
h) depositing a second conductive layer.

46. The method according to claim 45, wherein the width of the unexposed photoresist area over the edges of first conductive layer section in step d) is less than ⅙ the minimum width of the first conductive layer sections, but not less than 100 nm.

47. A method of forming the electronic device according to claim 28, wherein the device comprises, in order, the steps of:
a) patterning a first conductive layer on a substrate, each section of the first conductive layer having an upper surface, at least 3 edges and a distance between each of the edges;
b) depositing a photoresist over both the substrate and the patterned first conductive layer sections;
c) exposing to radiation regions of the photoresist over each of the first conductive layer sections only the regions lying along the upper surface of all of the edges of the section and over at least part of the support and leaving a region of unexposed photoresist over the first conductive layer between the exposed sections; the width of the unexposed section being less than the distances between the edges of the first conductive layer section;
d) removing the exposed photoresist to uncover the both at least of the substrate and part of the upper surface of each of the first conductive layer sections along each of the edges and leaving a section of insoluble unexposed photoresist whose width is less than every distance between the edges of the conductive layer section;
e) depositing a non-radiative active fluoropolymer layer over the substrate, the upper surface of the first conductive layer along all of the edges, and remaining insoluble unexposed photoresist over the first conduction layer section;
f) removing the remaining insoluble unexposed photoresist and its overlying fluoropolymer layer and uncovering the areas of the upper surface of the first conductive layer section, so that at least three fluoropolymer bank structures that each partially overlap the upper surface along each edge of the first conductive layer section are formed;
g) depositing at least one active layer over and in direct contact with the upper surface of the first conductive layer sections between the fluoropolymer bank structure; and
h) depositing a second conductive layer.

48. The method according to claim 47, wherein the width of the exposed photoresist area over the edges of the first conductive layer section in step d) is less than ⅙ the width of the first conductive layer sections but not less than 100 nm.

49. The method according to claim 45, wherein the at least one active layers are deposited using an inkjet method.

50. The method according to claim 45, wherein the non-radiative active fluoropolymer is selected from fluorinated poly(p-xylylene) polymers; amorphous fluoro polymers, fluorinated polyimides; Hyflon AD® series; polytetrafluoro-ethylene (PTFE); fluoro ethylene propylene polymers; polyvinylidene fluorides; fluoroethylene Vinyl Ether (FEVE) resins; fluorinated polynaphthalenes; fluorinated siloxanes; fluorinated amorphous carbon thin films (a-C:F); poly-4,5-difluorodioxoles; fluoro-urethane glycol based polymers; fluorinated poly-cyclic olefins; fluorinated polynorbonene; poly-1,1,2,4,4,55,6,7,7-decafluoro-3-oxa-1,6-heptadiene; and (CₓF_{y}) and (CF₂)ₓ.

51. The method according to claim 45, wherein the non-radiative active fluoropolymer layer is deposited in step e) by dissolving the fluoropolymer in a solvent in which the photoresist is not soluble, coating the substrate with the fluoropolymer solution and removing the solvent.

52. The method according to claim 45, wherein the non-radiative active fluoropolymer layer is deposited in step e) by a thermal evaporation, plasma or chemical vapour deposition technique.

53. The method according to claim 45, wherein the thickness of the insoluble photoresist layer deposited in step d) is at least 2 times the thickness of fluoropolymer layer deposited in step e).

54. The method according to claim 45, wherein a lift-off process for removal of the remaining insoluble photoresist and its overlying fluoropolymer layer in step f) uses an organic solvent in which the fluoropolymer is not soluble.
